(19) United States
(12) Patent Application Publication
(10) Pub. No.: US 2013/0001597 A1
(43) Pub. Date: Jan. 3, 2013

(54) Lighting Device Having a Color Tunable Wavelength Converter

(75) Inventors: Maria J. Anc, Groveland, MA (US); Kailash Mishra, Chelmsford, MA (US)

(73) Assignee: OSRAM SYLVANIA INC., Danvers, MA (US)

(21) Appl. No.: 13/170,365

(22) Filed: Jun. 28, 2011

(51) Int. Cl. H01L 33/50; H01L 33/08; B82Y 99/00

(52) U.S. Cl. 257/88; 257/98; 977/774; 257/E33.067

(57) ABSTRACT

There is herein described a lighting device including at least one LED and a wavelength converter. The wavelength converter includes a supporting plate, a plurality of first host sites and a plurality of second host site. The supporting plate is disposed over the LED. The plurality of the first host sites is disposed directly on a surface of the supporting plate. Each of the plurality of first host sites consists essentially of a first matrix and a plurality of first quantum dots dispersed in the first matrix. The first quantum dots have a first common emission peak wavelength. The plurality of the second host sites is disposed directly on the surface of the supporting plate. Each of the plurality of second host sites consists essentially of a second matrix and a plurality of second quantum dots dispersed in the second matrix. The second quantum dots have a second common emission peak wavelength. The second common emission peak wavelength is different from the first common emission peak wavelength.

### TECHNICAL FIELD

This invention relates to light emitting diode (“LED”) devices. In particular, this invention relates to wavelength converters for LED devices and LED devices containing the wavelength converters for converting the light emitted from a light source into light of different wavelengths.

### BACKGROUND

A typical white LED light source contains one or more blue-emitting LEDs and broad band down-converters such as YAG:Ce phosphors or phosphor blends. Phosphors may be deposited directly on the chip, disposed on a remote supporting surface, confined within a remote converter, or volume-incorporated into the optical components and packaging. In most cases, the blue light from the excitation source contributes to the output white light spectrum. Color characteristics of the light source depend on both the emission spectra of the blue-emitting LEDs and the broad band phosphors. Variability of the emission wavelength of blue-emitting LED requires binning processes and increases cost and complexity of fabrication.

It is also possible to create a white LED lighting device with a full phosphor conversion of the emission from the LED. Ultraviolet (UV), violet, and short-wavelength blue-emitting LEDs may be used with a combination of suitable phosphors. The full conversion approach is applicable to white, monochromatic, or special effect lighting devices. Color characteristics of the light of full conversion light sources are determined by the emission spectra of the phosphors.

In addition, white LED lighting devices may also be achieved by the combination of monochromatic LEDs, the combination of monochromatic and white LEDs, combination of various white LEDs, or combination of white LEDs and color correcting remote phosphor. This approach requires complex driving circuits, which increase complexity and cost. (For convenience, as used herein, LEDs and phosphors may also be referred to by the color of the light they emit. For example, blue-emitting LEDs may be called blue LEDs, yellow-emitting phosphors may be called yellow phosphors, etc.)

The above-mentioned approaches utilize traditional broad band phosphors containing rare earth activators and micron size particles. Scattering, Stokes shift, and re-absorption of emitted radiation are major sources of luminance losses during the conversion utilizing these phosphors.

Colloidal semiconductor light emitting nanocrystals, i.e. quantum dots (QDs) are non-scattering light emitters due to their nanosize scale. They can be produced by chemical synthesis methods and dispersed in organic solvents. The quantum dots exhibit narrow emission spectra with peak emissions having a full width at half maximum (FWHM) on the order of 50 nm or less. Thus, the emitted light from quantum dots has a rich, saturated, near monochromatic color. The emission wavelength of the colloidal quantum dots can be precisely tuned throughout the entire visible range by selecting the materials system and size of the nanocrystals. This enables very fine tuning of the emission color that is not attainable with conventional phosphors. Quantum dots exhibit broad and strong absorption spectra and low Stokes shift losses.

The absorption spectrum of one size (color) quantum dots can overlap with the emission spectrum of other (smaller) quantum dots. In such case, the emission from the smaller QDs will be re-absorbed and emitted at longer wavelength likely reducing overall conversion efficiency.

### SUMMARY OF THE INVENTION

It is an object of the invention to obviate the disadvantages of the prior art.

It is a further object of the invention to provide a wavelength converter minimizing re-absorption and an LED lighting device containing the same.

According to an embodiment, there is provided a lighting device including at least one LED and a wavelength converter. The wavelength converter includes a supporting plate, a plurality of first host sites and a plurality of second host sites. The supporting plate is disposed over the LED. The plurality of the first host sites is disposed directly on a surface of the supporting plate. Each of the plurality of first host sites consists essentially of a first matrix and a plurality of first quantum dots dispersed in the first matrix. The first quantum dots have a first common emission peak wavelength. The plurality of the second host sites is disposed directly on the surface of the supporting plate. Each of the plurality of second host sites consists essentially of a second matrix and a plurality of second quantum dots dispersed in the second matrix. The second quantum dots have a second common emission peak wavelength. The second common emission peak wavelength is different from the first common emission peak wavelength, chosen in a manner to produce specific color.

The disclosed wavelength converter blends the emission colors without intermixing or overlaying individual color quantum dots. Thus, the wavelength converter minimizes the possibility of self-absorption. The lighting device may utilize the unique properties of quantum dots for increased flexibility in tuning the color of the output light. The disclosed wavelength converter may be positioned remotely or deposited directly on the LED chip.

### BRIEF DESCRIPTION OF THE DRAWINGS

FIG. 1 is a schematic illustration of a lighting device according to an embodiment of the invention.

### DETAILED DESCRIPTION

For a better understanding of the present invention, together with other and further objects, advantages and capabilities thereof, reference is made to the following disclosure and appended claims taken in conjunction with the above-described drawings.

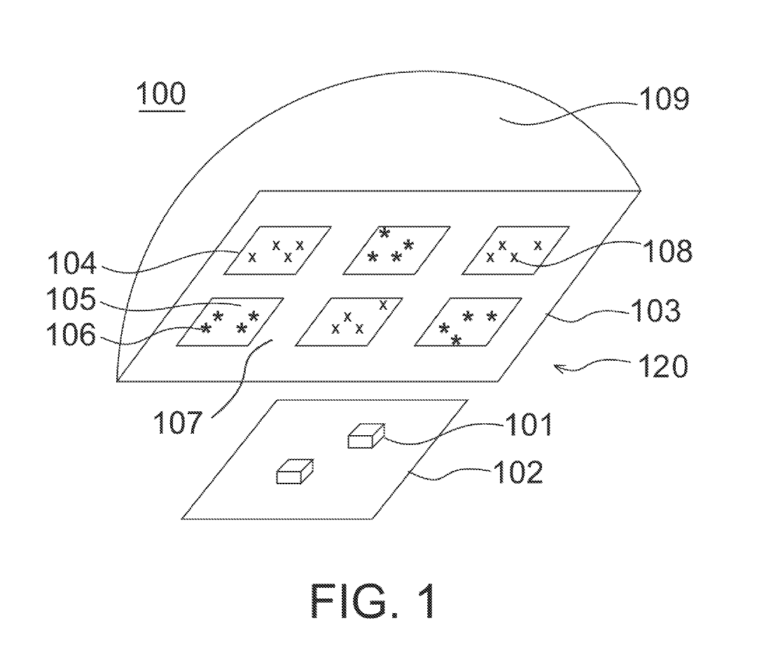

With reference to FIG. 1, a lighting device 100, in accordance with an embodiment of the invention is shown. One or more LEDs 101 are mounted on the circuit board 102. A wavelength converter 120 is disposed over the LEDs 101 so that the emitted light from the LEDs passes through the wavelength converter 120. The wavelength converter 120 may be disposed directly on top of the LEDs 101, or disposed remotely above the LEDs 101. The wavelength converter 120 comprises a supporting plate 103 that contains a plurality of host sites 104 directly on the surface of the supporting plate 103. Each of the host sites 104 contains a host matrix 105, which has a desired viscosity and optical performance. The host matrix 105 may contain a polymer, silicone, silica, glass or a combination thereof. Some of the host sites 104 contain one type of quantum dots 106 incorporated in the host matrix 105. All the quantum dots 106 have the same emission color, i.e. the same emission peak wavelength. The quantum dots 106 are dispersed in a suitable concentration in host matrices 105 for a desired optical performance after curing. Other host sites 104 may contain quantum dots 108 having another common color dispersed in host matrix 105. The host matrix 105 may be the same in each case, or it may be different for each type of quantum dots 106, 108. The emission peak wavelength of quantum dots 106 is different, preferably longer, than the emission peak wavelength of quantum dots 108. There may be an encapsulant 109 on top of the supporting plate 103 encapsulating the host sites 104. The material of the encapsulant 109 may be a polymer, glass, transparent composite, or a combination thereof. The lighting device 100 offers multiple benefits such as minimizing re-absorption, flexibility in color tuning, and optimization of color characteristics. In order to avoid re-absorption, all quantum dots in the same host site have the same emission peak wavelength. The light emitted from the LEDs passes through the host sites and is converted by quantum dots. Since all quantum dots within one host site have the same emission peak wavelength, the converted light is not re-absorbed or re-emitted by any quantum dots in the same host site. Since host sites 104 are directly deposited on the same supporting plate 103, the light emitted from one host site has minimum possibility to enter another host site and to be converted by quantum dots having different emission peak wavelengths.

In some embodiments, the lighting device may contain quantum dots having 2, 3 or more colors. The colors of quantum dots are determined by the emission peak wavelengths of the quantum dots. All quantum dots in the same host site have the same color; i.e. all quantum dots in the same host site have substantially the same emission peak wavelength. In some embodiments, the lighting device may contain some phosphor host sites. The phosphor host sites contain one or more types of traditional phosphors that are broad band phosphors, e.g. cerium-activated yttrium aluminum garnet (YAG:Ce).

In some embodiments, the host sites may be tightly packed so that there are substantially no vacant spaces between the host sites. In another embodiment, the spaces 107 between the host sites may be filled with quantum dots with shortest emission peak wavelength; or the spaces 107 between the host sites may be filled with broad band phosphors. Thus, all the surface of the supporting plate may be substantially occupied by the host sites containing quantum dots and broad band phosphors. In such embodiments, the LEDs are preferably ultraviolet (UV) LEDs and substantially all the UV light emitted from the UV LEDs is converted by the quantum dots and broad band phosphors. As a result, the output light of the lighting device may be comprised entirely by the converted light.

In some embodiments, the host sites are loosely packed so that the spaces 107 between the host sites are vacant. The vacant spaces contain no matrix, quantum dots, or broad band phosphors. In such cases, the LEDs are preferably blue LEDs. The blue light emitted from the blue LEDs passes through the vacant spaces without any conversion. Therefore, the blue light from the LED contributes as a part of the resulting output spectrum from the lighting device.

In some embodiments, the supporting plate may be transparent. In another embodiment, the supporting plate may contain one or more broad band phosphors, preferably a YAG:Ce phosphor, dispersed in polymer.

In some embodiments, the host sites may have different shapes including, but not limited to, a square, circle, rectangle, hexagon, or triangle. In some embodiments, the surface of the supporting plate may be uneven. For example, the surface of the supporting plate may compose at least a portion of a sphere and may enclose the LEDs inside of the sphere. In some embodiments, the surface of the supporting plate may be functionalized to facilitate site confinement or to prevent excessive spreading of the composite. For example, the surface of the supporting plate may be functionalized by treatment of agents modifying surface energy. The surface of the supporting plate may be textured. In some embodiments, the encapsulant may enclose the entire wavelength converter.

In some embodiments, the host sites may be adjacent to each other. The host sites may have a dot pitch of less than 0.05 mm, preferably less than 0.01 mm, more preferably less than 0.005 mm. The dot pitch of the host sites is defined as the average distance between the centers of two neighboring host sites. It is preferably to have small dot pitch so that the output light from the lighting device appears as a uniform and smooth illumination without any screen door effect to the users. The small dot pitch also discounts the need of a diffuser which reduces the lumen efficacy of the lighting device.

A number of mass-production methods including, but not limited to, molding, stamping, printing, deposition with ink dispensers, ink-jet printers, roll-to-roll may be applicable for fabrication of such host sites containing quantum dots and broad band phosphors on the supporting plate.

While the principles of the invention have been described herein, it is to be understood by those skilled in the art that this description is made only by way of example and not as a limitation as to the scope of the invention. Reference numerals corresponding to the embodiments described herein may be provided in the following claims as a means of convenient reference to the examples of the claimed subject matter shown in the drawings. It is to be understood however, that the reference numerals are not intended to limit the scope of the claims. Other embodiments are contemplated within the scope of the present invention in addition to the exemplary embodiments shown and described herein. Modifications and substitutions by one of ordinary skill in the art are considered to be within the scope of the present invention, which is not to be limited except by the recitations of the following claims.

What is claimed is:

1. A lighting device comprising:
at least one LED;
a wavelength converter disposed over the LED, the wavelength converter comprising a supporting plate, a plurality of first host sites and a plurality of second host sites;
the plurality of first host sites being disposed directly on a surface of the supporting plate, each of the plurality of first host sites consisting essentially of a first matrix and a plurality of first quantum dots dispersed in the first matrix, wherein the first quantum dots have a first common emission peak wavelength; and
the plurality of second host sites being disposed directly on the surface of the supporting plate, each of the plurality of second host sites consisting essentially of a second matrix and a plurality of second quantum dots dispersed in the second matrix, wherein the second quantum dots have a second common emission peak wavelength and the second common emission peak wavelength is longer than the first common emission peak wavelength.

2. The lighting device of claim 1, further comprising a plurality of third host sites disposed directly on the surface of the supporting plate, each of the plurality of third host sites consisting essentially of a third matrix and a plurality of third quantum dots dispersed in the third matrix, wherein the third quantum dots have a third common emission peak wavelength and the third common emission peak wavelength is different than the first and second common emission peak wavelengths.

3. The lighting device of claim 2, wherein the third common emission peak wavelength is shorter than the first and second common emission peak wavelengths.

4. The lighting device of claim 1, further comprising a plurality of third host sites disposed directly on the surface of the supporting plate, each of the plurality of third host sites comprising a broad band phosphor.

5. The lighting device of claim 1, wherein the wavelength converter further has one or more vacant spaces, wherein a light emitted from the LED passes through the vacant spaces without conversion from the first or second quantum dots.

6. The lighting device of claim 1, wherein the supporting plate is transparent.

7. The lighting device of claim 1, wherein the supporting plate comprises a polymer and a broad band phosphor.

8. The lighting device of claim 7, wherein the broad band phosphor is a YAG:Ce phosphor.

9. The lighting device of claim 1, further comprising an encapsulant on top of the supporting plate encapsulating the first and second host sites.

10. The lighting device of claim 1, further comprising an encapsulant enclosing the wavelength converter.

11. The lighting device of claim 10, wherein the encapsulant comprises at least one material selected from a polymer, transparent composite, and glass.

12. The lighting device of claim 1, wherein the first and second host sites have a shape selected from a square, circle, rectangle, hexagon, and triangle.

13. The lighting device of claim 1, wherein the first matrix comprises at least one material selected from a polymer, silicone, silica, and glass.

14. The lighting device of claim 1, wherein the second matrix comprises at least one material selected from a polymer, silicone, silica, and glass.

15. The lighting device of claim 1, wherein the LED is an ultraviolet or blue LED.

16. The lighting device of claim 1, wherein the surface of the supporting plate is uneven, textured, or functionalized.

17. The lighting device of claim 1, further comprising a plurality of LEDs.

18. The lighting device of claim 1, wherein the host sites are spaced apart from each other and at least a portion of the space between the host sites contains quantum dots or a broad band phosphor.

19. The lighting device of claim 1, wherein the host sites are adjacent to each other.

20. The lighting device of claim 1, wherein the host sites have a dot pitch of less than 0.05 mm.

21. The lighting device of claim 20, wherein the host sites have a dot pitch of less than 0.01 mm.
